(19) United States
(12) Patent Application Publication
(10) Pub. No.: US 2007/0178301 A1
(43) Pub. Date: Aug. 2, 2007

(54) Antisoiling dlc layer

(75) Inventors: Sophie Camelio, Buxerolles (FR); Thierry Girardeau, Quinsay (FR); Nicolas Maitre, Conflans Ste Honorine (FR); Luc Nouvelet, Paris (FR)

Correspondence Address: FULBRIGHT & JAWORSKI L.L.P., 600 CONGRESS AVE., SUITE 2400, AUSTIN, TX, 78701, US

(73) Assignee: Essilor International Compagnie Generate d'Optique, Charenton-le-Pont (FR)

(21) Appl. No.: 10/571,743

(22) PCT Filed: Feb. 21, 2006
(86) PCT No.: PCT/FR06/50153

§ 371 Date: Mar. 20, 2007

(30) Foreign Application Priority Data
Feb. 22, 2005 (FR) 0550489

(51) Int. Cl. C23C 16/26; B05D 5/06; G11B 5/64; B32B 9/00

(52) U.S. Cl. 428/336; 427/162; 427/249.7; 428/409; 428/688; 428/701

(57) ABSTRACT

The present invention relates to a substrate comprising two main sides, at least one of which comprises a non-reflecting coating, characterized in that an air-contacting outer layer is deposited onto said non-reflecting coating, said outer layer having a thickness of 10 nm or less, a surface energy of less than 60 mJ/m² and a surface presenting a contact angle with oleic acid of less than 70°.

The present invention relates to a substrate comprising a surface-treated, non-reflecting coating, the optical properties of which are relatively soil-resistant, said substrate being very easy to clean.

Non-reflecting coatings are in particular used in the field of ophthalmic lenses, especially spectacle glasses.

There are usually mono- or multilayered coatings classically obtained by means of a metal oxide vacuum deposition.

These coatings have many benefits from the optical point of view, improving in particular the visual comfort of the wearer.

However they unfortunately suffer from being soil-sensitive, and especially to greasy deposits such as those resulting from finger marks.

Soil has two major effects, on the one hand it is harmful to the view perception of the wearer, in that it damages transmission of the transmitted light beams that are perceived by the wearer and, on the other hand, it creates aesthetically unpleasant effects, by locally modifying on the glass surface the intensity and the colour of the reflection such as perceived by a foreign observer.

For this reason the ophthalmic glass latest generation most frequently comprises hydrophobic and/or oleophobic surface coatings, deposited on the non-reflecting coatings, that reduce surface energy thereof so as to prevent greasy soils to adhere, thereby making them easier to remove.

Hydrophobic and/or oleophobic coatings are obtained by applying surface energy-reducing compounds onto the non-reflecting coating surface.

Such compounds have been extensively described in the prior art, for example in the patents U.S. Pat. No. 4,410,563, EP 0,203,730, EP 749,021, EP 844,265, EP 933,377.

Silane based-compounds bearing fluorinated moieties, in particular one or more perfluorocarbon or perfluoropolyether moietie(s), are most often used. Examples thereof include silazane, polysilazane or silicone compounds comprising one or more fluorinated moieties such as those previously mentioned.

An especially efficient known method consists in depositing onto the non-reflecting coating compounds bearing fluorinated moieties and Si—R moieties, R corresponding to an OH group or a precursor thereof, preferably an alkoxy group. Generally, classical hydrophobic and/or oleophobic coatings have a thickness of less than 10 nm and produce a surface energy of less than 20 mJ (millijoules)/m², and of less than 15 mJ/m² for the most efficient.

These coatings do satisfy many wearers.

However, even if such treated non-reflecting coatings are easier to clean, it often remains necessary in practice to use special, microfiber type, wiping clothes and/or to repeat many times a wiping step so as to recover optical properties nearly identical to those of the glass prior to being soiled.

DLC-based thin layers (Diamond-Like Carbon) have already been described in the state of the art.

WO92/05951 describes inorganic substrates coated with at least one DLC type layer and their application in the field of ophthalmic lenses, in particular sunglasses.

The substrates comprise an intermediate layer inserted between the substrate and an optically substantially transparent DLC outer layer, that has been deposited by evaporation.

Especially described are layer stacks deposited from the substrate, in such an order: a first interlayer, a second interlayer, a DLC layer, another interlayer, a DLC type outer layer.

The thickness of these different layers may be chosen so as to minimise or maximise light reflection in a predetermined wavelength range.

WO92/05951 indicates that the benefit of such stacks is to possess a better abrasion resistance as compared to classical optical coatings.

DLC coating is preferably effected through deposition by means of an ion gun using a hydrocarbon gas, in particular methane, or carbon steam.

The DLC layer thickness may range from 10 angstroms to 10 micrometers, preferably is at least 200 angstroms.

Example Q describes reflecting stacks deposited in this order starting from substrate's surface made of SiO₂ mineral glass (75 nm)/DLC (55 nm)/SiO₂ (75 nm)/DLC (55 nm). The so coated substrate may be used as solar glass and has a blue-yellow sheen.

The American patent U.S. Pat. No. 5,190,807 describes identical type stacks on an organic substrate that has been itself coated with a polysiloxane layer of one or more intermediate layer(s), that may contain metal oxides or metal nitrides.

The substrates are sunglass lenses and are mostly made of polycarbonate.

The final stack abrasion resistance, as well as its durability are the major characteristics mentioned for these products.

The American patent U.S. Pat. No. 6,077,569 describes a method for producing non-reflecting coatings having a mirror effect on lenses such as ophthalmic lenses, especially for sunglass lenses.

It is stated that dielectric materials used include DLC materials.

This material may be used as a component of one of the multiple layers constituting the stack, or may be used as top or outer layer of the stack, in which case the DLC layer offers an additional protection against abrasion and a satisfactory chemical resistance. The patent does precise that DLC layer high atomic density, as well as the hydrophobic nature, the hardness and the low friction coefficient thereof result in a stack having a longer durability, a better abrasion resistance and a good cleanability.

In this patent, stack first coating is a composite transparent coating with a high abrasion resistance.

This abrasion-resistant coating, preferably ranging from 5 to 20 micrometers is obtained by ion-aided deposition from an organosilane or organosilazane plasma.

In the previously mentioned documents, the DLC layer is used for its traditional properties, and mainly for improving the abrasion resistance and the durability of the products onto which it has been deposited.

These properties need to use a DLC layer sufficient thickness, that is why the DLC layer is in practice at least 20 nm thick.

WO92/05951 indicates in particular that to improve the stack abrasion resistance, it is preferred to provide for several DLC layers being integral part of the stack, which makes it possible to increase the whole thickness of deposited DLC coating.

While the deposition of a thick layer on the surface of a mirror-type reflecting stack is possible since it contributes in this disposal to the reflective effect due to its high refractive index, on the contrary, it is impossible with non-reflecting stacks to use such an outer layer which thickness provides a significant antiabrasion effect because it does then seriously impair the non-reflecting properties.

The abovementioned documents do not point towards deposition of DLC layers having antiabrasion properties onto the surface of a non-reflecting coating.

It is an object of the present invention to provide a substrate comprising a non-reflecting stack, the optical properties of which, especially as regards transmittance, are not, or not very, affected by soils, especially by finger marks.

It is another object of the present invention to provide a substrate comprising a relatively soil-resistant and easy to clean non-reflecting coating basing on a classical stack, without having to modify the stack structure and materials thereof.

It is another object of the invention to provide a non-reflecting stack that is relative soil-resistant, without substantially impairing the non-reflecting stack performances.

It is another object of the invention to provide a substrate comprising a non-reflecting coating together with a high optical transmittance, despite soils on the surface thereof.

The hereabove objectives are aimed at by providing a substrate comprising two main sides, at least the one of which comprises a non-reflecting coating onto which an air-contacting outer layer is deposited, having a thickness of 10 nm or less, the surface energy of which is less than 60 mJ/m² and the surface of which has a contact angle with oleic acid of less than 70°.

Indeed, the inventors did observe that by depositing onto the surface of a non-reflecting stack a low surface energy-, oleophilic, ultrafine layer, the transmittance optical properties of the non-reflecting stack-coated substrate were practically unaffected by soils deposited onto the non-reflecting stack, unlike traditionally used non-reflecting coatings carrying hydrophobic and oleophobic top coats previously described.

In the practice, should the substrate be a spectacle ophthalmic lens, this means that the wearer's vision is not very affected or not affected at all by soils.

More precisely, and without wishing to be bound by any theory, it is considered that soil deposition results in locally adding an additional layer of greasy material onto the non-reflecting stack, which causes the optical properties thereof to be damaged by affecting on the one hand incident light ray transmission and, on the other hand, the reflection of the same rays. In particular, the residual reflection colour is generally locally modified in the smudged area.

The inventors have observed that the soil deposited onto hydrophobic and oleophobic top coats that are used nowadays as outer layer deposited onto non-reflecting stacks comes as microdroplets which are easy to remove from the surface because of the low surface energy, but which do scatter light.

On the contrary, in the present case, because of the oleophilic nature of the surface, the soil is distributed more evenly on the surface, to form after wiping a thin, very little scattering, quasi-film.

The preferred outer layers are those having a contact angle with oleic acid of 40° or less, more preferably of 30° or less, even more preferably of 20° or less, and most preferably of 15° or less.

In general, the outer layer will be selected with the lowest surface energy as possible, while keeping the oleophilic properties as previously described.

Thus and preferably, the surface energy of said outer layer is less than 55 mJ/m², more preferably less than 50 mJ/m², even more preferably less than 45 mJ/m², and most preferably less than 30 mJ/m².

Surface energy is calculated according the Owens and Wendt method described in the following reference: “Estimation of the surface force energy of polymers” Owens D. K., Wendt R. G. (1969) J. APPL. POLYM.SCI, 13, 1741-1747.

To form the ultrafine layer of low-surface energy oleophilic material, any type of material or combination of materials can be used that produces the required oleophilic and surface energy properties.

Suitable examples include silicon and fluorine-containing DLC layers. Such layers are described for example in the article entitled “M. Grishke (1998) Diamond and related materials, 7, 454-458”.

These layers are produced using plasma methods based on, (as an example) HMDSO (hexamethyidisiloxane) or TMS (trimethyl silane) for silicated films and on CF₄ for fluorinated layers.

A DLC material is a material especially suitable for implementing the present invention.

DLC materials have been extensively described in the literature and may be defined as an amorphous carbon metastable form comprising a significant fraction of sp³ C—C bonds. There can be materials comprising only carbon or hydrogenated alloys referred to as a-C:H.

DLC layer properties as well as methods for producing the same are described especially in the article entitled “Diamond-like amorphous carbon”; J. Robertson; Materials science and engineering R37 (2002) 129-181.

Preferably, the DLC material comprises a a-C:H material.

Layers made of such material are relatively hydrophobic (contact angle with water=82°) and highly oleophilic (contact angle avec oleic acid=12°).

This type of material may be defined as sp² hybridized carbon clusters, most of them being aromatic in nature, distributed throughout a matrix having sp³ hybridized carbon-carbon bonds, that are more or less hydrogenated.

The a-C:H material-containing layer is deposited by means of a plasma-enhanced chemical vapour deposition.

The plasma-enhanced chemical vapour deposition method (traditionally referred to as PECVD) consists by applying a voltage in producing a condensation reaction on the sample surface between a reactive gas and such surface, the reactive gas being partly ionized in the form of a plasma.

Plasma is produced by ionizing at least partly a gas comprising a hydrocarbon, such as CH₄, C₂H₂, C₂H₄ and C₆H₆, preferably methane CH₄.

During such ionization process, in the case of methane, CH₃⁺, C₂H₅⁺, H⁺ ions are produced that will bombard the substrate. The plasma also comprises CH₃., C₂H₅., H radicals.

During the deposition process of said layer, the substrate is in contact with a cathode coupled to a radio frequency generator.

Self-bias voltage applied between the electrode bearing the substrate (cathode) and the plasma represents an important parameter for defining the structural state of the resulted DLC films, and in particular a-C:H ones. Generally speaking, the hydrogen concentration decreases as the self-bias voltage applied to the cathode increases as expressed in absolute value.

With a zero self-bias voltage, the a-C:H material sp² areas of the deposited layer are small in size and dispersed into this highly hydrogenated sp³ matrix. The mechanical properties of such layer look like those of a polymer and are relatively poor.

Near to a self-bias voltage of 150 volts, as expressed in absolute value, the sp³ matrix becomes less hydrogenated and a maximal sp³ carbon-carbon hybridization is obtained, as well as good mechanical properties.

With high self-bias voltages of about 400 volts as expressed in absolute value, the graphitic cluster size increases, the layer becoming more absorbent and less hard.

The a-C:H material used in the frame of the present invention comprises generally a hydrogen atom atomic percentage ranging from 30 to 55%, and more preferably greater than 43%.

These a-C:H materials are deposited by generally imposing to the cathode a self-bias voltage ranging from 0 to −400 volts, preferably from 0 to −150 volts, and more preferably from −10 to −50 volts.

During the deposition process, gas pressure generally varies from 10⁻² mbars to 10⁻¹ mbars.

Said outer layer refractive index at 25° C. and 630 nm varies from 1.58 to 2.15, preferably from 1.60 to 2.10.

Preferably, said outer layer thickness varies from more than 2 nm to 10 nm, and more preferably from 3 to 8 nm.

With such reduced thickness values, the DLC layer absorption remains poor. As previously mentioned, it is moreover possible to minimize this absorption by working with cathode low self-bias voltages during the deposition process of this layer, as expressed in absolute value.

Self-bias voltages ranging from 0 to −50 volts are especially recommended, preferably from −10 to −50 volts, this latter voltage range enabling to combine a low coefficient of extinction with satisfactory mechanical properties (hardness).

In particular, for increasing the a-C:H layer thickness, a-C:H materials will be preferably used having a coefficient of extinction at 400 nm lower than 0.20, preferably lower than 0.15.

The non-reflecting coating onto which the layer is deposited may be a non-reflecting coating traditionally known in the previous art.

As an example, the non-reflecting coating may comprise a dielectric material, mono- or multilayered film such as SiO, SiO₂, Si₃N₄, TiO₂, ZrO₂, Al₂O₃, MgF₂ or Ta₂O₅, or combinations thereof.

This non-reflecting coating is generally deposited by vacuum deposition according to any of the following methods:

1. evaporation, optionally ion beam assisted.

2. ion beam sputtering.

3. cathode sputtering, optionally magnetron assisted.

4. plasma enhanced chemical vapor deposition.

Beside vacuum deposition, a sol/gel mineral layer deposition may also be envisaged (for example from a tetraethoxy silane hydrolysate).

Should the film comprise a single layer, its optical thickness must correspond to λ/4 (λ being a wavelength ranging from 450 to 650 nm).

Should the non-reflecting coating comprise a plurality of layers, this then is a stack coating alternating between high refractive index material layers and low refractive index material layers. Typically, a high index means n_{D}²⁵≧1.55, preferably ≧1.60; a low index means n_{D}²⁵<1.50, preferably <1.45.

Should the multilayered film comprise three layers, a combination may be used corresponding to the respective optical thickness λ/4, λ/2, λ/4 or λ/4−λ/4−λ/4.

Moreover, an equivalent film may be used comprising more layers, instead of any number of layers belonging to the three abovementioned layers.

The Rm reflection coefficient (reflection averaged in the 400-800 nm wavelength range) of the substrate side coated with said non-reflecting coating and of said outer layer is less than 2.5%.

Preferably, the coated side Rm reflection coefficient is less than 2%, more preferably less than 1.5% and most preferably less than 1%.

The non-reflecting coating generally has a physical thickness of less than 700 nm, preferably less than 500 nm.

Preferably, the non-reflecting coating is a multilayered coating.

The high refractive index material for the non-reflecting coating is preferably selected from metal oxides.

The low refractive index material is preferably selected from silicon oxides, in particular SiO₂. The non-reflecting coating is preferably deposited by evaporation.

The non-reflecting stack may comprise one or more DLC layers, although it preferably does not comprise any DLC material-containing layer.

The air-contacting outer layer, which thickness is 10 nm or less, which surface energy is less than 60 mJ/m² and which surface has a contact angle with oleic acid less than 70° is preferably deposited onto a low refractive index, silicon oxide-containing layer corresponding to the outermost non-reflecting coating layer as compared to the substrate.

Non-reflecting coatings may be deposited on any suitable substrate such as organic or mineral glass, for example for ophthalmic lenses, in particular spectacle glasses, wherein the substrates may be nude or optionally coated with one or more coating(s), preferably an antiabrasion coating, itself preferably deposited onto an impact-resistant primer and/or and adhesion-promoting primer.

Preferably the non-reflecting coating is deposited onto an antiabrasion coating.

Optionally, an undercoating or a foundation layer may be deposited between the antiabrasion coating and the non-reflecting coating.

Suitable examples include silica-based undercoatings, that may be up to more than 100 nm thick, or undercoatings comprising Cr or niobium or oxides thereof, that are generally finer, i.e. typically less than 10 nm thick.

Preferably, the antiabrasion coating is a polysiloxane or methacrylate coating. It is preferably obtained by deposition and hardening of a sol comprising at least one alkoxy silane such as an epoxy silane, preferably a trifunctional one, and/or a hydrolysate thereof, obtained for example through hydrolysis with a HCl hydrochloric acid solution. Following the hydrolysis step, which generally lasts for between 2 h and 24 h, preferably between 2 h and 6 h, catalysts are optionally added. A surfactant is preferably also added so as to enhance the coating optical quality.

Preferred epoxy-alkoxy silanes comprise one epoxy moiety and three alkoxy moieties, these later being directly bound to the silicon atom.

A preferred epoxy-alkoxy silane may be an alkoxy silane bearing β-(3,4-epoxy cyclohexyl) moiety, such as β-(3,4-epoxy cyclohexyl)ethyltrimethoxy silane.

Especially preferred epoxy-alkoxy silanes have following formula (I):

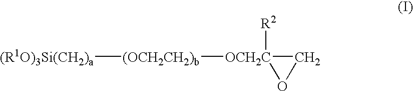

wherein:

R¹ represents an alkyl moiety having from 1 to 6 carbon atoms, preferably a methyl or ethyl moiety,

R² represents a methyl moiety or a hydrogen atom,

a is an integer between 1 and 6,

b is 0, 1 or 2.

Examples of such epoxy silanes include γ-glycidoxy propyl triethoxy silane or γ-glycidoxy propyl trimethoxy silane.

γ-glycidoxy propyl trimethoxy silane is preferably used.

Examples of epoxy silanes that can be used also include epoxydialkoxy silanes such as γ-glycidoxy propylmethyl dimethoxy silane, γ-glycidoxy propylmethyl diethoxy silane and γ-glycidoxy ethoxypropylmethyl dimethoxy silane.

However epoxydialkoxy silanes are preferably used in lower amounts than the previously mentioned epoxy trialkoxy silanes.

Other preferred alkoxy silanes have following formula:
R³_{c}R⁴_{d}SiZ_{4 -(}c+d) (II)

wherein R³ and R⁴ are selected from alkyl, methacryloxyalkyl, alkenyl and aryl groups substituted or not (substituted alkyl moieties are for example halogenated, especially chlorinated or fluorinated alkyl groups); Z represents an alkoxy, alkoxy alkoxy or acyloxy group; c and d are 0, 1 or 2, respectively; and the sum c+d is 0, 1 or 2. This formula includes following compounds: (1) tetraalkoxy silanes, such as methyl silicate, ethyl silicate, n-propyl silicate, isopropyl silicate, n-butyl silicate, sec-butyl silicate, and t-butyl silicate, and/or (2) trialkoxy silanes, trialkoxyalkyl silanes or triacyloxysilanes, such as methyltrimethoxy silane, methyltriethoxy silane, vinyltrimethoxy silane, vinyltriethoxy silane, vinyltrimethoxyethoxysilane, vinyltriacetoxy silane, phenyltrimethoxy silane, phenyltriethoxy silane, γ-chloropropyl-trimethoxy silane, γ-trifluoropropyltrimethoxy silane, methacryloxypropyltrimethoxy silane, and/or (3) dialkoxy silanes, such as: dimethyidimethoxy silane, γ-chloropropylmethyldimethoxy silane and methylphenyidimethoxy silane.

When using an alkoxy silane hydrolysate, this is prepared in a manner known per se.

Methods detailed in the patents EP 614957 and U.S. Pat. No. 4,211,823 may be carried out.

Silane hydrolysate is prepared for example by adding water or a hydrochloric acid or sulphuric acid solution to the silane(s), in presence of a solvent. It is also possible to implement hydrolysis without adding any solvent and by simply using alcohol or carboxylic acid formed upon reaction between water and the alkoxy silane(s). These solvents may also be substituted for with other solvent types, such as alcohols, ketones, alkyl chlorides and aromatic solvents.

Hydrolyzing with a hydrochloric acid aqueous solution is preferred.

Beside alkoxy silanes, the solution may also comprise inorganic material particles such as metal oxide or oxyhydroxide, or silica particles.

Suitable examples of such particles include silica, or high refractive index particles such as titanium oxide or zirconium particles.

The sol/gel composition comprises preferably at least one hardening catalyst.

Suitable examples of hardening catalysts include especially aluminium compounds, and in particular aluminium compounds selected from:
aluminium chelates, and
compounds having formulas (III) or (IV) as detailed hereafter: 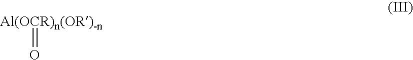
   (R′O)₃₋ₙAl(OSiR″₃)ₙ (IV)

wherein:

R and R′ are linear or branched chain alkyl moieties having from 1 to 10 carbon atoms,

R″ represents a linear or branched chain alkyl moiety having from 1 to 10 carbon atoms, a phenyl moiety, a group

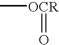

where R has the same definition as given hereabove, and n is an integer of 1 to 3.

As already known, an aluminium chelate is a compound obtained by reacting an alcoholate or aluminium acylate with sequestering agents free from nitrogen and sulfide, comprising oxygen as coordination atom.

The aluminium chelate compound is preferably selected from compounds having formula (V):
AlXᵥY₃₋ᵥ (V)

wherein:

X represents an OL moiety where L represents an alkyl moiety having from 1 to 10 carbon atoms,

Y represents at least one ligand produced from a compound having formula (1) or (2):
M¹CO CH₂COM² (1)
M³CO CH₂ COOM⁴ (2)

wherein:

M¹, M², M³ and M⁴ represent alkyl moieties having from 1 to 10 carbon atoms,

et v is 0, 1 or 2.

Suitable examples of compounds of formula (V) include aluminium acetylacetonate, aluminium ethylacetoacetate bisacetylacetonate, aluminium bisethylacetoacetate acetylacetonate, aluminium di-n-butoxide monoethylacetoacetate and aluminium diipropoxide monomethylacetoacetate.

Suitable examples of compounds of formula (III) or (IV) include preferably those wherein R′ represents an isopropyl or ethyl moiety, and R and R″ represent methyl moieties.

Using an acetyl-acetonate aluminium will be particularly advantageous, preferably as composition hardening catalyst in an amount ranging from 0.1 to 5% by weight, as compared to the total weight of the composition.

Antiabrasion coating compositions may also comprise one or more additive(s), such as pigments, ultraviolet absorbers, photochromic dyes, anti-yellowing agents, antioxidants.

As previously mentioned, antiabrasion coating compositions may further comprise an organic solvent, the boiling point of which ranges preferably from 70 to 140° C. at the atmospheric pressure.

Suitable organic solvents to use according to the invention include alcohols, esters, ketones, tetrahydropyrane, tetrahydrofurane and mixtures thereof.

Alcohols are preferably selected from lower alcohols (C₁-C₆), such as methanol, ethanol and isopropanol.

Esters are preferably selected from acetates, in particular ethyl acetate.

The composition may further comprise one or more surfactants, in particular fluorinated or fluorosiliconized surfactants, generally in an amount ranging from 0.001 to 1% by weight, preferably from 0.01 to 1% by weight, as compared to the total weight of the composition. The preferred surfactants include FLUORAD® FC430 marketed by 3M, EFKA 3034® marketed by EFKA, BYK-306® marketed by BYK and Baysilone OL31® marketed by BORCHERS.

The theoretical solid contents of the coating composition preferably represent from 1 to 50% by weight mineral colloids, more preferably from 3 to 35% by weight, and even more preferably from 10 to 35% by weight.

The theoretical solid content weight corresponds to the solid content total weight calculated for the different components of the final coating composition.

As used herein, the “solid content weight of silanes” defines the calculated weight as expressed in Qk Si O(4−k)/2 units wherein Q is an organic moiety directly bound to the silicone atom through a Si—C bond and Qk SiO(4−k)/2 results from Qk Si R′″(4−k) where Si—R′″ gives SiOH upon hydrolysis, and k is 0,1 or 2.

Any classical deposition method may be used to deposit the antiabrasion coating layer.

Dip-coating is another deposition method, wherein the substrate to be coated is dipped into a composition bath, as well as spin-coating deposition.

The sol is preferably deposited by means of spin coating, that is to say by centrifugation, onto substrates, for example an ORMA® substrate, made by Essilor, based on diethylene glycol poly(bisallyl carbonate). The deposition rate ranges from 100 rpm to 3000 rpm, preferably from 200 rpm to 2000 rpm.

Varnishes are then hardened, preferably by means of a heat treatment in an oven for a time ranging from 1 to 5 hours, typically for 3 hours at a temperature ranging from 80° C. to 120° C.

Antiabrasion layer thickness varies from 1 to 10 micrometers, preferably from 3 to 8 micrometers.

Any type of impact-resistant primer layers traditionally used for transparent polymer material articles, such as ophthalmic lenses, may be used as impact-resistant primer layer.

Preferred primer compositions include thermoplastic polyurethane-based compositions, such as those described in the Japanese patents 63-141001 and 63-87223, poly(meth)acrylic primer compositions, such as those described in the American patent U.S. Pat. No. 5,015,523, thermosetting polyurethane-based compositions, such as those described in the European patent EP-0,404,111 and poly(meth)acrylic latex-based and polyurethane latex-based compositions, such as those described in the patent specifications U.S. Pat. No. 5,316,791 and EP-0,680,492.

Preferred primer compositions are those based on polyurethane and those based on latex, in particular on polyurethane type latex.

Poly(meth)acrylic latex are copolymer latex mainly derived from a (meth)acrylate, such as for example ethyl (meth)acrylate or butyl (meth)acrylate, or methoxy or ethoxyethyl (meth)acrylate, with generally a minor amount of at least one other comonomer, such as for example styrene.

Preferred poly(meth)acrylic latex are acrylate-styrene copolymer latex.

Such acrylate-styrene copolymer latex are marketed by ZENECA RESINS under the trade name NEOCRYL®.

Polyurethane type latex are also known and available on the market.

Examples thereof include polyurethane latex comprising polyester units. Such latex are also marketed by ZENECA RESINS under the trade name NEOREZ® and by BAXENDEN CHEMICAL under the trade name WITCOBOND®.

Mixtures of such latex may also be used in the primer compositions, in particular a mixture of polyurethane latex with poly(meth)acrylic latex.

These primer compositions may be deposited onto the sides of the optical article by dipping or centrifugation, then are dried at a temperature of at least 70° C. and up to 100° C., preferably of about 90° C., for a time ranging from 2 minutes to 2 hours, generally of about 15 minutes, to form primer layers which after curing are 0.2-2.5 μm thick, preferably 0.5-1.5 μm thick.

Amongst organic glass substrates that are suitable for optical articles according to the invention, there are polycarbonate substrates and those obtained by polymerizing alkyl methacrylates, in particular C₁-C₄ alkyl methacrylates, such as methyl (meth)acrylate and ethyl (meth)acrylate, polyethoxylated aromatic (meth)acrylates such as polyethoxylated bisphenolate dimethacrylates, allyl derivatives such as linear or branched, aliphatic or aromatic, polyol allyl carbonates, thio-(meth)acrylic compounds, polythiourethane, polycarbonate (PC) and polyepisulfide substrates.

There are amongst recommended substrates those which are obtained by polymerizing polyol allyl carbonates, including ethyleneglycol bis allyl carbonate, diethylene glycol bis 2-methyl carbonate, diethyleneglycol bis (allyl carbonate), ethyleneglycol bis (2-chloro allyl carbonate), triethyleneglycol bis (allyl carbonate), 1,3-propanediol bis (allyl carbonate), propylene glycol bis (2-ethyl allyl carbonate), 1,3-butylenediol bis (allyl carbonate), 1,4-butenediol bis (2-bromo allyl carbonate), dipropyleneglycol bis (allyl carbonate), trimethyleneglycol bis (2-ethyl allyl carbonate), pentamethyleneglycol bis (allyl carbonate), isopropylene bisphenol-A bis (allyl carbonate).

Especially recommended are substrates obtained by polymerizing diethyleneglycol bis allyl carbonate, marketed under the trade name CR 39® by PPG INDUSTRIES (lens ORMA® ESSILOR).

There are also amongst recommended substrates, those obtained by polymerizing thio(meth)acrylic monomers, such as those described in the French patent application FR-A-2,734,827.

Substrates may obviously be obtained by polymerizing mixtures of the above monomers.

Prior to deposition, the substrate's surface may be activated by a suitable treatment, such as a plasma or corona treatment, or using an acid or basic aqueous solution so as to form reactive sites that will provide a better adhesion to the antiabrasion coating composition.

The following examples illustrate the present invention without being limitative.

All depositions have been conducted in a RF capacitive discharge PECVD reactor (Plasma Enhanced Chemical Vapour Deposition). In this technology, the deposition results from reactions proceeding within the plasma (ionization, dissociation) of the gas precursor (CH₄) molecules.

A vane pump and a diffusion pump generate in the reactor a 3×10⁻⁶ mbar vacuum prior to depositing. Pressure control can be monitored by means of thermocouple gauges and hot cathode gauge, before experimentation, and thanks to a Pirani gauge during deposition. A throttle gate valve disposed around the edges of the deposition chamber is operated during the experiment, that enables to thus obtain a pressure varying from a few millitorrs to a hundred millitorrs for low gas flow rates, typically 20 cm³/s for CH₄, giving a 10⁻² mbar pressure.

The deposition chamber comprises two electrodes essential for generating plasma and depositing. There are two metallic disks with a 10 cm radius. First of them is full and is 4 mm thick: it is used for depositions onto silicon substrates. The second one is 1 cm thick and has three circular holes (radius 6.5 cm and thickness 4 mm) where ophthalmic glasses with a dioptric power of “−2” or “0” (glass with no power) are inserted.

Before deposition, the substrate-supporting electrode is placed in an air-lock system where a rough vacuum is created. The electrode is then automatically directed to the deposition chamber. Using an air-lock system makes it possible to continually maintain the deposition chamber under vacuum conditions between two experiments.

The different operating modes depend on where the incident power is applied.

I.A Substrate-Supporting Electrode in Self-Bias Mode.

Power is applied on the substrate-supporting electrode, that becomes then self-biased. The applied power variation causes the self-bias voltage to vary and acts thus on the energy of the ions bombarding the surface during the layer growth. Two powers (40 and 85 W) have been applied, corresponding to two self-bias voltages respectively −35 V and −150 V. The self-bias voltage is normally negative, although sometimes expressed in absolute value.

Experiment Procedure for Producing a Low Self-Bias Voltage a-C:H Layer (U=35 V).

1. place in the air-lock system a suitable substrate-supporting electrode that carries the samples.

2. close the door.

3. apply vacuum in the deposition chamber.

4. once rough vacuum is made in the air-lock system, the electrode automatically tilts in the deposition chamber.

5. wait until a 3×10⁻⁶ torr ultimate vacuum is obtained and turn the hot cathode gauge off.

6. select the “etch” operating mode.

7. close the throttle gate valve.

8. set the argon flow rate at 20 cm³/s, then open the argon supply valve.

9. select a 50 W incident power (“applied power”), that corresponds to a 100 V substrate self-bias voltage (“platform voltage”).

10. set on one minute the deposition time.

11. press the “power” button so as to prime plasma.

12. once the cleaning is completed, close the argon supply valve, open the throttle gate valve and turn the hot cathode gauge on.

13. wait until a 3×10⁻⁶ torr ultimate vacuum and turn the hot cathode gauge off.

14. close the throttle gate valve.

15. set the methane flow rate on 20 cm³/s, then open the methane supply valve.

16. select a 20 W incident power (“applied power”) that corresponds to a −35 V substrate self-bias voltage (“platform voltage”).

17. set the deposition time on 1 hour and 20 minutes to produce a deposition of about 100 nm, on 5 minutes for a thickness of about 6 nm and on 2 minutes 30 for a thickness of about 3 nm.

18. press the “Power” button so as to prime the plasma.

19. once deposition is completed, close the methane supply valve, open the throttle gate valve and turn the hot cathode gauge on.

20. press the “unload” button so as to tilt up the substrate-supporting electrode again in the air-lock system, prior to automatically purging back from gas to air.

21. unload the substrate-supporting electrode out of the reactor.

Experiment Procedure for Producing a High Self-Bias Voltage a-C:H Layer (U=150 V).

The procedure is the same as hereabove except for the steps 16 and 17 which are substituted for by following steps:

16. select a 85 W incident power (“applied power”) corresponding to a −150 V substrate self-bias voltage (“platform voltage”).

17. set the deposition time on 40 minutes for producing a deposition of about 100 nm, on 2 minutes 30 for a thickness of about 6 nm and on 1 minute 15 for a thickness of about 3 nm.

IB. Cathode Sputtering Mode for “Ground Depositions”

Power is applied onto the target electrode, that is then self-biased. Since layer structural modifications and optical property changes mainly depend on incident ion energy and since the substrate is always grounded according to this mode, only one power (85 W) has been applied.

Experiment Procedure for Producing a Grounded -a-C:H Layer.

The procedure follows low self-bias voltage deposition steps, except an additional step 14b is after step 14, and step 16 and 17 that are replaced as described hereafter.

14b is. select operating mode cathode sputtering.

16. select a 85 W incident power (“applied power”) which corresponds to a −250 V target self-bias voltage (“turret voltage”).

17. set deposition time on 30 minutes for producing a deposition of about 100 nm, on 1 minute 44 for a thickness of about 6 nm and on 52 seconds for a thickness of about 3 nm.

The continuation of the specification refers to the figures which illustrate respectively:

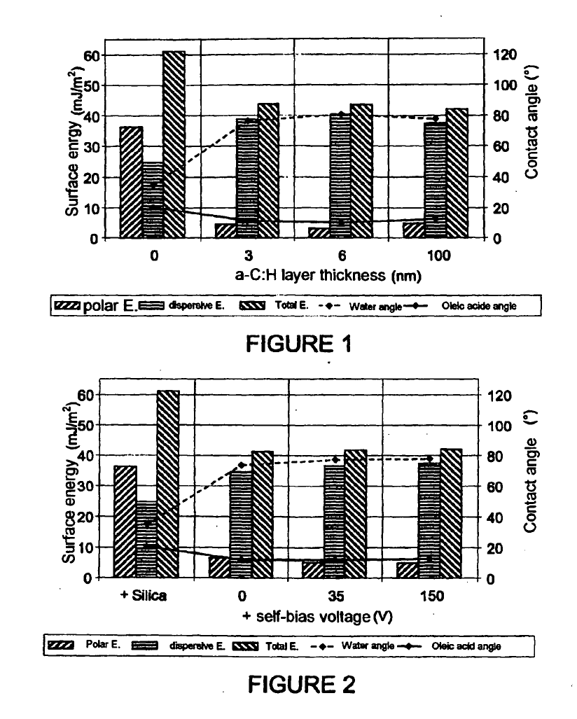

FIG. 1 a graph showing surface energy values and contact angle values for substrates coated or not with a a-C:H layer according to the invention depending on the a-C:H layer thickness;

FIG. 2 a graph showing surface energy values and contact angle values for substrates coated or not with a a-C:H layer according to the invention depending on the self-bias voltage;

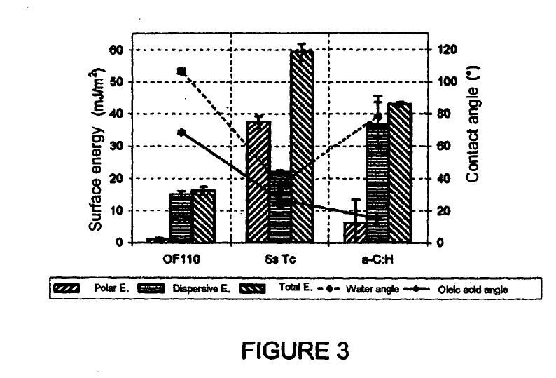

FIG. 3 a graph showing surface energy values and contact angle values for substrates coated or not with a a-C:H layer according to the invention or with hydrophobic and/or oleophobic coatings of the prior art.

Contact angle measurements are static contact angle measurements and have been effected by means of the DIGIDROP apparatus marketed by GBX. It makes it possible to evaluate a contact angle starting from a picture taken at a given moment (3000 ms) after deposition of a droplet from different liquids: water, diiodomethane, formamide and oleic acid. The a-C:H material surface energy evaluation has been made by the Owens-Wendt method.

Two cleanability tests were conducted. Both were different from each other as regards the nature of the deposited soil.

One cleaning test (test A) used herein consisted in depositing a soil stain of 20 mm diameter (reconstituted sebum, essentially comprising oleic acid) onto an ophthalmic glass, and in executing in a reproducible manner wiping operations in a back and forth motion (wiping in one direction, then coming back corresponding by definition to two wiping passes); with a cotton cloth (made by Berkshire) with a 750 g load.

The second cleaning test (Test B) was conducted with finger marks deposited by three operators. Each operator transferred on 3 glasses two adjacent marks for each test series. Results thus correspond to an average from 9 viewing measurements.

Each operator ran a finger across his forehead before applying it on a new glass.

Wiping passes were then effected according to the same procedure as in test A.

A visual examination based on a transmittance assay facing a light source (ultraviolet tube) was conducted in each step of the test. (After 0, 2, 10, 20, 70, 150, 200 wiping passes). The glass cleanliness condition is evaluated on a 3 score-scale:

3—substantially visible mark

2—not very visible mark

1—clean glass (no visible mark)

### Contact Angle and Surface Enegry Measurements

### Example 1

Silicon Substrate Deposition.

Substrates coated with a-C:H layers using an uniform self-bias voltage (−150 V) of different thicknesses (3, 6 and 100 nm) as well as substrates coated with a-C:H layers using different self-bias voltages (0, −35 V and −150 V) of the same thickness (100 nm) were prepared according to the procedures previously defined.

Flat silicon chips covered with a silica layer of about 80 nm obtained by cathode sputtering were used as substrates.

Surface energy and contact angle values for these substrates are given in FIGS. 1 and 2.

Comparatively, the values for the initial, non-coated substrate (thickness=0 nm) are given.

Whatever the deposition conditions, the same surface energy values are kept for a-C:H layers. Thus, 3 nm are sufficient for giving to the layer the a-C:H material-specific contact angle behavior.

Curves clearly show the oleophilic character of the a-C:H films, since the contact angle with oleic acid is very low (≈12°). On the contrary, the a-C:H material does not show any substantial hydrophilicity (contact angle with water ≈78°).

The behavior with both liquids is confirmed by the surface energy value and the two following components:
oleic acid, which is a relatively a polar fluid, wets almost perfectly the a-C:H layer surface. In other respects, the dispersive component of the surface energy is rather strong.
Water, which is a polar fluid, wets only very little the a-C:H film surface. In other respects, the polar component of the surface energy is weak.

### Examples

### Deposition on Reflection-Treated Ophthalmic Glasses

### Example 2

Wettability Measurements

Several ORMA®) ophthalmic glasses (ESSILOR), of power −2.00 dioptries, coated with a 1 micrometer thick polyurethane primer coating, with an approx. 3 micrometer thick antiabrasion coating such as defined in example 3 of the European patent EP614957 and with a non-reflecting multilayered coating ZrO2/SiO2/ZrO2/SiO2 deposited in this order starting from the antiabrasion coating (outer layer=SiO₂) were characterized as regards contact angles for various coatings (top coats) deposited onto the last silica layer of the non-reflecting multilayered coating described hereabove.

Each series comprises three glasses and three measures per glass were taken. In addition to a product of the prior art (OF110), wettability performances of only one a-C:H (35 V, 3 nm) glass series were studied.

FIG. 3 shows that glasses treated with an Optron OF110 top coat are hydrophobic and relatively highly oleophobic.

On the contrary, glasses with no top coat, wherein the non-reflecting coating second silica layer is in contact with air, reveal a hydrophilic and oleophilic character.

a-C:H layer-coated glasses show a relative hydrophobicity and a high oleophilicity.

### Example 3

Cleaning Test Results

A first series of cleanability experiments was carried out (test A such as previously described).

a-C:H layer-coated non-reflecting glasses (−150 V; 6 nm)—such as described in example 2—were tested, then identical non-reflecting glasses that had been a-C:H-coated (3 nm) and treated with different self-bias voltages (−150 V, −35 V, 0 V).

Finally, a-C:H-treatment behavior was compared to a marketed hydrophobic and oleophobic top coat (OF110, OPTRON), and without top coat.

After reconstituted sebum deposition, the cleanliness score was 3.

As for contact angle measures, cleaning test behavior for a-C:H-treated glasses seems to be the same, whatever the carbon layer thickness, either 6 or 3 nm (table 1).

TABLE 1
Cleaning test A

| | Wiping pass number to get score: | |
|---|---|---|
| | 2 - not very | |
| Sample | visible marks | 1 - clean |
| A-C:H layer (−150 V, 6 nm) | 2 | 40 |
| A-C:H layer (−150 V, 3 nm) | 2 | 40 |
| A-C:H layer (−35 V, 3 nm) | 2 | 20 |
| A-C:H layer (grounded, 3 nm) | 2 | 40 |
| AR with no top coat | 70 | 200 |
| OF110 top coat | 40 | 70 |

Table 1 also shows that whatever the self-bias voltages (−150 V, −35 V, 0 V), the cleanability behavior remained unchanged.
hardly deposited soil mark viewing (0 wiping) was lower with an oleophilic surface (a-C:H, with no top coat) than with an oleophobic surface (OF110). The inventors observed that soil rather forms a not very scattering, thin film in the case of an oleophilic surface. On the contrary, with an oleophobic surface, the soil came as more scattering droplets.
On a-C:H glasses, soil mark viewing decreased very rapidly. The soil remained for a long time on the surface, but became nearly imperceptible since it formed a non-scattering, thin film.

Prior art fluorinated top coats (OF110) behaved fully differently: the viewing reduction was far much less abrupt as compared to what was observed with a-C:H material.

Only the strongly oleophilic surface (a-C:H) provided an abrupt viewing reduction after 2 wiping passes.

A second series of cleaning test (Test B) was carried out.

Each operator put two adjacent marks on 3 OF110-treated glasses, 3 glasses with no top coat and 3 a-C:H-treated glasses (3 nm thick, self-bias voltage −35 V). Results thus correspond to an average from 9 viewing measurements.

Immediately after reconstituted sebum deposition, the cleanliness score was 3. Soil viewing was strongly marked for OF110.

TABLE 2
cleaning test B (finger marks)

Wiping pass number to get score:

| | 2- not very | |
|---|---|---|
| Sample | visible marks | 1-clean |
| A-C:H layer | 2 | 40 |
| AR with no top coat | 70 | >100 |
| OF110 top coat | 40 | >50 |

Results confirm the tests conducted with reconstituted sebum soil deposition (test A).

Moreover, as regards the mechanical properties, a traditional series of tests (N10 runs such as described in the patent EP 947 601 (ESSILOR), Bayer, steel wool) was conducted on non-reflecting glasses coated with a a-C:H layer (−35 V, 3 nm) deposited on a non-reflecting coating.

It was observed that the a-C:H layer deposition had no effect on the mechanical properties.

1.-36. (canceled)

37. A substrate comprising two main sides, at least one of which comprises a non-reflecting coating and an air-contacting outer layer deposited on the non-reflecting coating, the outer layer having a thickness of 10 nm or less, having a surface energy of less than 60 mJ/m², and a surface having a contact angle with oleic acid of less than 70°.

38. The substrate of claim 37, wherein the thickness of the outer layer is from 2 nm to 10 nm.

39. The substrate of claim 38, wherein the thickness of the outer layer is from 3 to 8 nm.

40. The substrate of claim 37, wherein the contact angle with oleic acid is 40° or less.

41. The substrate of claim 40, wherein the contact angle with oleic acid is 30° or less.

42. The substrate of claim 41, wherein the contact angle with oleic acid is 20° or less.

43. The substrate of claim 42, wherein the contact angle with oleic acid is 15° or less.

44. The substrate of claim 37, wherein the surface energy of the outer layer is less than 55 mJ/m².

45. The substrate of claim 44, wherein the surface energy of the outer layer is less than 50 mJ/m².

46. The substrate of claim 45, wherein the surface energy of the outer layer is less than 45 mJ/m².

47. The substrate of claim 46, wherein the surface energy of the outer layer is less than 30 mJ/m².

48. The substrate of claim 37, wherein the outer layer comprises a DLC material.

49. The substrate of claim 48, wherein the DLC material comprises an a-C:H material.

50. The substrate of claim 49, wherein the a-C:H material comprises a hydrogen atom atomic percentage ranging from 30 to 55%.

51. The substrate of claim 50, wherein the a-C:H material comprises a hydrogen atom atomic percentage greater than 43%.

52. The substrate of claim 37, wherein the outer layer has a refractive index at 25° C. and 630 nm of from 1.58 to 2.15.

53. The substrate of claim 52, wherein the refractive index is from 1.60 to 2.10.

54. The substrate of claim 37, wherein the Rm reflection coefficient of the substrate side coated with the non-reflecting coating and of the outer layer is less than 2.5%.

55. The substrate of claim 54, wherein the coated side has an Rm reflection coefficient of less than 2%.

56. The substrate of claim 55, wherein the coated side has an Rm reflection coefficient of less than 1.5%.

57. The substrate of claim 56, wherein the coated side has an Rm reflection coefficient of less than 1%.

58. The substrate of claim 37, wherein the non-reflecting coating has a physical thickness of less than 700 nm.

59. The substrate of claim 58, wherein the non-reflecting coating has a physical thickness of less than 500 nm.

60. The substrate of claim 37, wherein the non-reflecting coating is a multilayered coating.

61. The substrate of claim 60, wherein the multilayered coating is a stack of alternating high refractive index material layers and low refractive index material layers.

62. The substrate of claim 61, wherein at least one high refractive index material layer comprises a metal oxide.

63. The substrate of claim 62, wherein at least one low refractive index material layer comprises a silicon oxide.

64. The substrate of claim 37, wherein the non-reflecting coating does not comprise any DLC material.

65. The substrate of claim 37, wherein the outer layer is directly on a low refractive index material layer comprising a silicon oxide representing the outermost layer of a non-reflecting coating.

66. The substrate of claim 37, wherein the outer coating further comprises an antiabrasion coating.

67. The substrate of claim 66, wherein the antiabrasion coating is on an impact-resistant primer layer.

68. The substrate of claim 66, wherein an undercoating or foundation layer is deposited between the antiabrasion coating and the non-reflecting coating.

69. The substrate of claim 37, wherein the substrate is an organic material substrate.

70. The substrate of claim 37, further defined as an ophthalmic lens.

71. The substrate of claim 70, wherein the ophthalmic lens is a spectacle glass.

72. A method comprising:
providing a substrate comprising two main sides, at least one of which comprises a non-reflecting coating; and
depositing on the non-reflecting coating an air-contacting outer layer having a thickness of 10 nm or less, a surface energy of less than 60 mJ/m², and a surface having contact angle with oleic acid of less than 70°.

73. The method of claim 72, wherein the outer layer comprises a DLC material.

74. The method of claim 73, wherein the DLC material comprises a a-C:H material.

75. The method of claim 74, wherein the a-C:H material has a hydrogen atom atomic percentage ranging from 30 to 55%.

76. The method of claim 75, wherein the a-C:H material has a hydrogen atom atomic percentage greater than 43%.

77. The method of claim 74, wherein the a-C:H material-containing layer is deposited by plasma-enhanced chemical vapor deposition.

78. The method of claim 72, wherein, during the deposition of the layer, the substrate is in contact with a cathode coupled to a radio frequency generator.

79. The method of claim 72, wherein the plasma is obtained by at least partially ionizing a hydrocarbon-containing gas.

80. The method of claim 79, wherein the hydrocarbon-containing gas comprises CH₄, C₂H₂, C₂H₄, or C₆H₆.

81. The method of claim 78, wherein the cathode has a self-bias voltage of from 0 to −400 volts.

82. The method of claim 81, wherein the self-bias voltage is from 0 to −150 volts.

83. The method of claim 82, wherein the self-bias voltage is from −10 to −50 volts.

84. The method of claim 72, wherein the pressure of the gas is from 10⁻² to 10⁻¹ mbars.
